(19) United States
(12) Patent Application Publication
(10) Pub. No.: US 2011/0159694 A1
(43) Pub. Date: Jun. 30, 2011

(54) METHOD FOR FABRICATING SEMICONDUCTOR DEVICE

(76) Inventors: Young-Bang Lee, Gyeonggi-do (KR); Ok-Min Moon, Gyeonggi-do (KR)

(21) Appl. No.: 12/833,278

(22) Filed: Jul. 9, 2010

(30) Foreign Application Priority Data
Dec. 30, 2009 (KR) 10-2009-0134229

(51) Int. Cl. H01L 21/311

(52) U.S. Cl. 438/703; 257/E21.257

(57) ABSTRACT

A method for fabricating a semiconductor device includes: providing a substrate, forming an insulation layer, an adhesive layer, and a photoresist pattern, etching the adhesive layer using the photoresist pattern as an etch barrier, and wet etching the insulation layer using the etched adhesive layer and the photoresist pattern as etch barriers.

### CROSS-REFERENCE TO RELATED APPLICATIONS

The present application claims priority of Korean Patent Application No. 10-2009-0134229, filed on Dec. 30, 2009, which is incorporated herein by reference in its entirety.

### BACKGROUND OF THE INVENTION

Exemplary embodiments of the present invention relate to a technology for fabricating a semiconductor device, and more particularly, to a method for fabricating a semiconductor device by using a photoresist layer pattern as an etch barrier and wet etching an insulation layer.

Diverse constituent structures of a semiconductor device are generally formed through a photolithography process. The photolithography process includes coating an etch target layer with a photoresist (PR) layer and forming a photoresist layer pattern by selectively exposing the photoresist layer.

A semiconductor device, such as Dynamic Random Access Memory (DRAM), includes a cell region where a plurality of unit cells are formed and a peripheral circuit region where a peripheral circuit for controlling the unit cells is formed. The cell region and the peripheral circuit region are formed through separate processes. When a predetermined constituent structure is to be formed in the cell region, the peripheral circuit region is covered with an insulation layer or a photoresist layer.

FIGS. 1A to 1C are cross-sectional views illustrating a conventional method for fabricating a semiconductor device. FIG. 2 is a photograph showing a concern with the conventional method.

Referring to FIG. 1A, an insulation layer 12 is formed over a substrate 11 including a cell region where a cell gate 14 is formed and a peripheral circuit region. The insulation layer 12 protects constituent structures already formed in the cell region and the peripheral circuit region during each other's process.

Subsequently, a photoresist layer pattern 13 is formed on the insulation layer 12 to form the predetermined constituent structure in the cell region using a cell open mask.

Referring to FIG. 1B, the insulation layer 12 is etched using the photoresist layer pattern 13 as an etch barrier. Hereafter, the etched insulation layer 12 will be referred to as an insulation layer pattern 12A.

Referring to FIG. 1C, after the photoresist layer pattern 13 is removed, the predetermined constituent structure is formed in the cell region using the insulation layer pattern 12A as a protective layer.

According to the conventional technology, a wet etch process is used to protect the constituent structure, already formed in the cell region, from being damaged during a process of etching the insulation layer pattern 12A using the photoresist layer pattern 13 as an etch barrier. However, etchant may permeate into the interface between the insulation layer pattern 12A and the photoresist layer pattern 13 due to weak adhesion between the insulation layer pattern 12A and the photoresist layer pattern 13 (see reference numeral ‘100’ of FIG. 1B). The effect caused by the weak adhesion between the insulation layer pattern 12A and the photoresist layer pattern 13 becomes worse as the integration degree of a semiconductor device increases, in other words, as the line width of a pattern decreases and the aspect ratio increases.

When the adhesion between the insulation layer pattern 12A and the photoresist layer pattern 13 is not sufficiently strong, as illustrated in reference symbol ‘A’ of FIG. 1C and reference symbol ‘A’ of FIG. 2, the etchant permeates into the interface between the insulation layer pattern 12A and the photoresist layer pattern 13 and the insulation layer pattern 12A may be over-etched. Also, due to the over-etched insulation layer pattern 12A, a constituent structure formed in the peripheral circuit region may be exposed and damaged by the etchant, or the constituent structure formed in the peripheral circuit region may be damaged during a subsequent process for forming a predetermined constituent structure in the cell region.

In order to resolve the above-described effects, a method of shifting a cell open mask is suggested. According to the method of shifting a cell open mask, when a cell open mask is shifted, the insulation layer pattern 12A may still be lost due to the weak adhesion between the insulation layer pattern 12A and the photoresist layer pattern 13 but the above-described effects may be prevented from occurring. However, the insulation layer pattern 12A may remain in an unnecessary region, and the insulation layer pattern 12A remaining in an unnecessary region may increase the number of procedural steps or cause a failure in a subsequent process. In short, the advantage of the method of shifting a cell open mask is traded off with its disadvantages.

### SUMMARY OF THE INVENTION

An exemplary embodiment of the present invention is directed to a semiconductor device fabrication method that may improve the adhesion between a photoresist layer pattern and an insulation layer.

Another exemplary embodiment of the present invention is directed to a semiconductor device fabrication method that may prevent the insulation layer from being over-etched during a process of wet-etching the insulation layer using the photoresist layer pattern as an etch barrier.

In accordance with an exemplary embodiment of the present invention, a method for fabricating a semiconductor device includes: providing a substrate, sequentially forming an insulation layer, an adhesive layer, and a photoresist pattern on the substrate, etching the adhesive layer using the photoresist pattern as an etch barrier, and wet etching the insulation layer using the etched adhesive layer and the photoresist pattern as etch barriers.

The adhesive layer may include a monosilicon layer, and etching of the adhesive layer may be performed using a mixed solution of nitric acid (HNO₃) and hydrofluoric acid (HF).

The thickness of the adhesive layer may range from approximately 100 Å to approximately 200 Å.

In accordance with another exemplary embodiment of the present invention, a method for fabricating a semiconductor device includes: providing a substrate including a cell region and a peripheral circuit region, sequentially forming an insulation layer and a silicon layer on the substrate, forming a photoresist pattern on the silicon layer using a cell open mask, etching the silicon layer using the photoresist pattern as an etch barrier, and wet etching the insulation layer using the silicon layer and the photoresist pattern as etch barriers.

### BRIEF DESCRIPTION OF THE DRAWINGS

FIGS. 1A to 1C are cross-sectional views illustrating a conventional method for fabricating a semiconductor device.

FIG. 2 is a photograph showing a semiconductor device fabricated by the conventional method.

FIGS. 3A to 3D are cross-sectional views illustrating a method for fabricating a semiconductor device in accordance with an exemplary embodiment of the present invention.

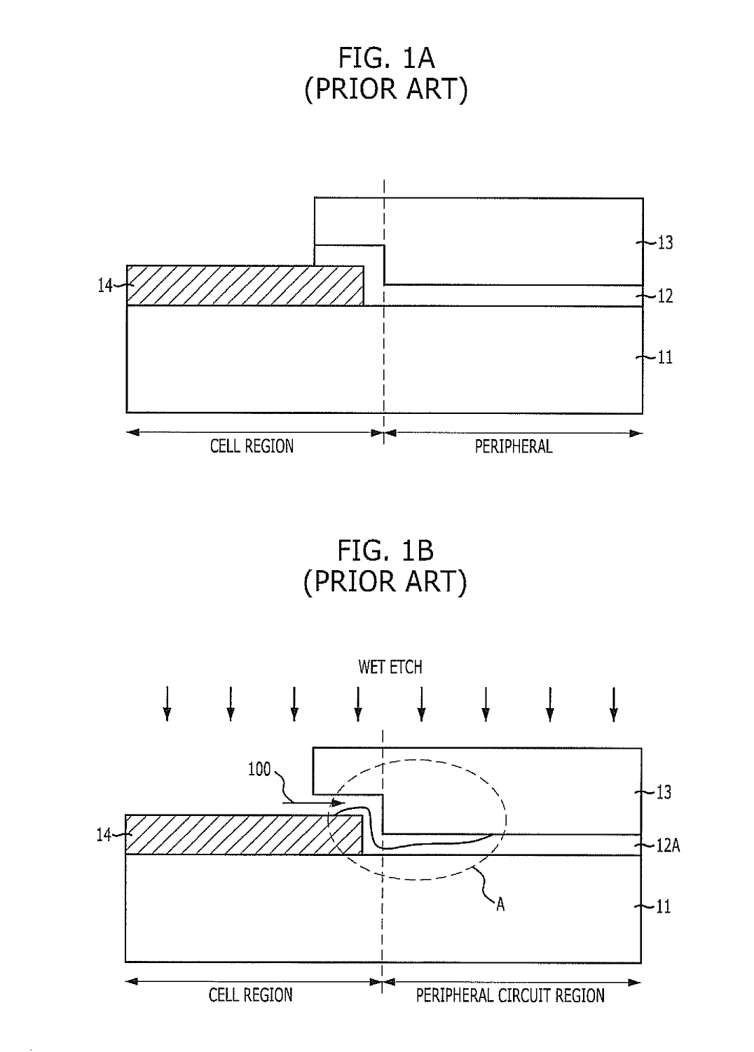

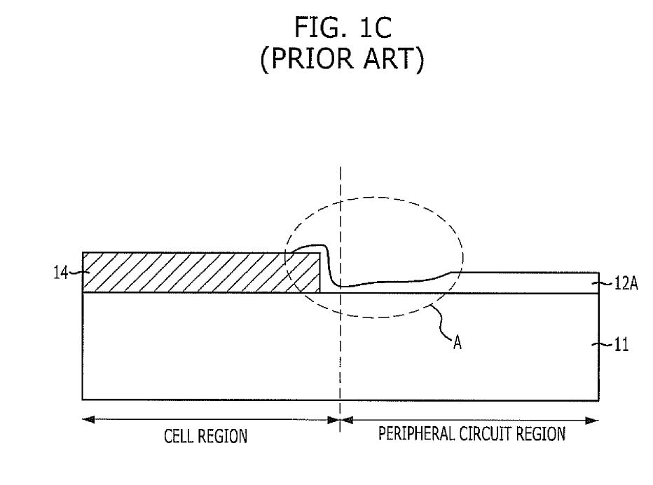

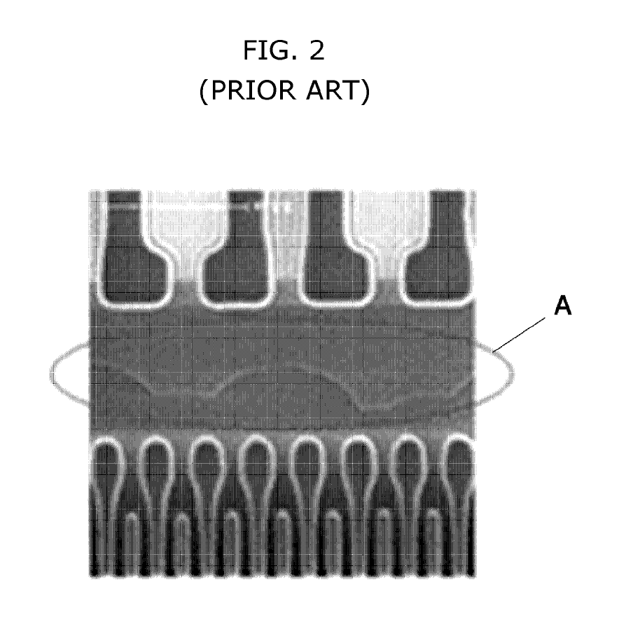

### DESCRIPTION OF EXEMPLARY EMBODIMENTS

Exemplary embodiments of the present invention will be described below in more detail with reference to the accompanying drawings. The present invention may, however, be embodied in different forms and should not be construed as being limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

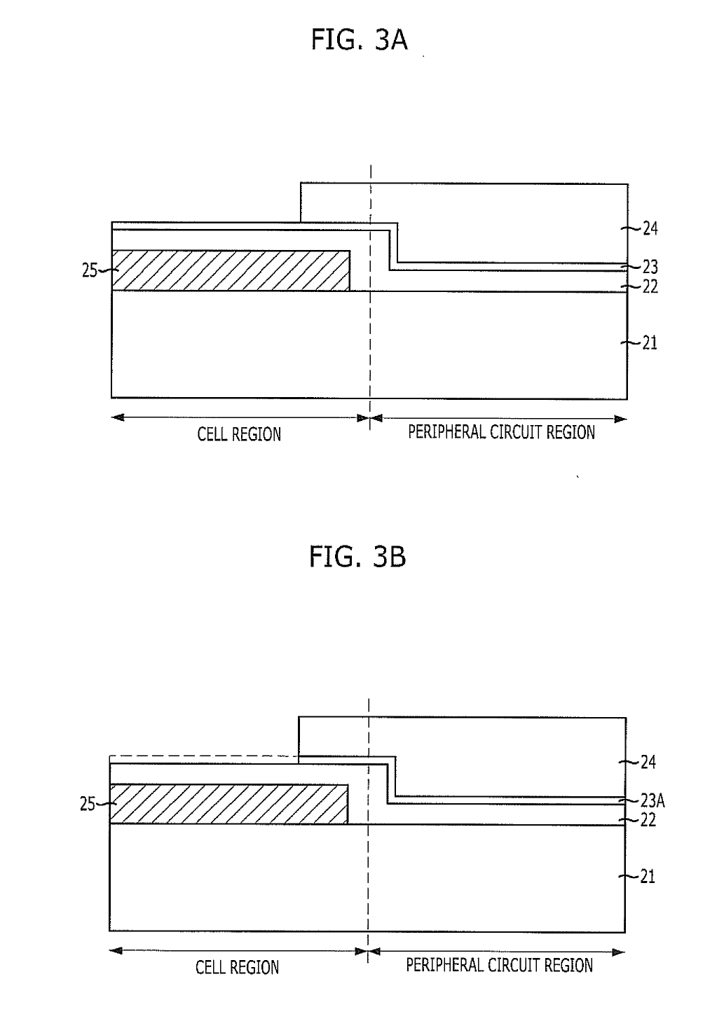

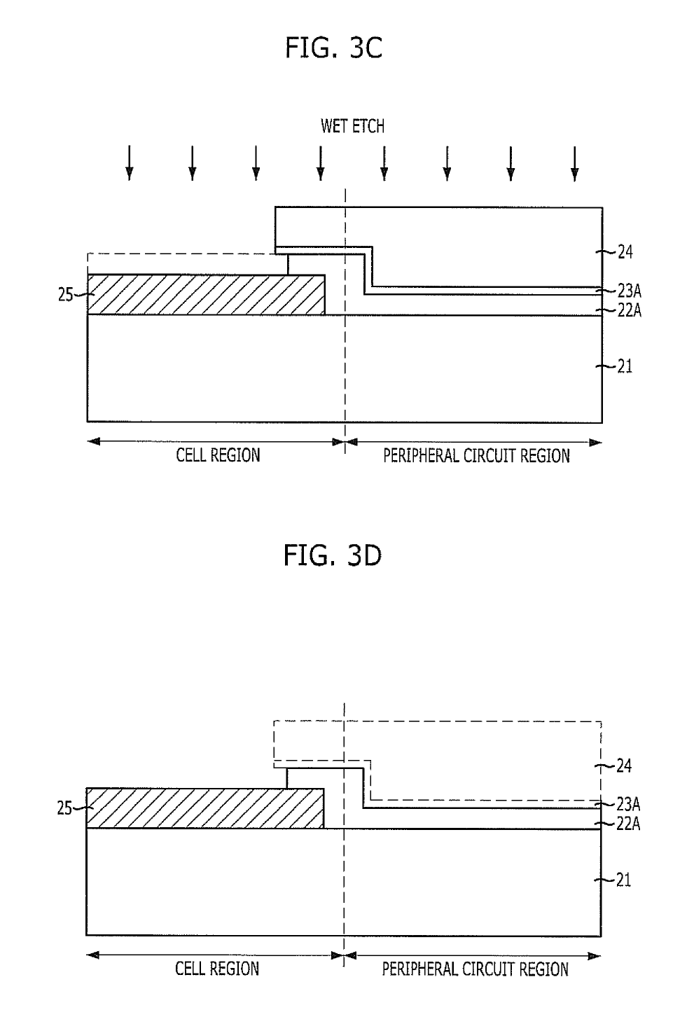

FIGS. 3A to 3D are cross-sectional views illustrating a method for fabricating a semiconductor device in accordance with an exemplary embodiment of the present invention.

Referring to FIG. 3A, an insulation layer 22 is formed over a substrate 21 including a first region and a second region, each of which includes predetermined constituent structures. Herein, the first region may be a cell region, and the predetermined constituent structure formed in the first region may be a cell gate 25. The second region may be a peripheral circuit region, and the predetermined constituent structure formed in the second region may be a peripheral gate (not shown) or a peripheral gate insulation layer (not shown) for a peripheral gate.

Herein, the insulation layer 22 protects a constituent structure already formed in the second region or the first region to which a process is not processed yet during a subsequent process of forming a predetermined constituent structure in the first region or the second region. In one embodiment of the present invention, which will be described hereafter, it is assumed that the insulation layer 22 is an oxide layer. The insulation layer 22 may be formed of diverse insulating materials other than oxides.

Subsequently, an adhesive layer 23 is formed over the insulation layer 22. The adhesive layer 23 has improved adhesion between a photoresist layer pattern 24, which will be formed in a subsequent process, and the insulation layer 22. The adhesive layer 23 is formed of a material having an etch selectivity with respect to the insulation layer 22.

A silicon layer may be used for the adhesive layer 23. The silicon layer may be one selected from the group consisting of a monosilicon layer, a polysilicon layer, and an amorphous silicon layer. It is preferred that the silicon layer may be a monosilicon layer without grain boundaries because grain boundaries may form a transfer path or permeation path of an etchant.

Since the silicon layer has a cubic structure, which is a stable crystallization structure, the silicon layer has few surface defects and surface roughness, as compared with the insulation layer 22, such as an oxide layer. In other words, the silicon layer has a planar surface, compared with the surface of the insulation layer 22, such as an oxide layer. For this reason, the adhesion between the photoresist layer pattern 24 and the insulation layer 22 may be improved.

Also, the adhesive layer 23 may be formed to have a thickness ranging from approximately 100 Å to approximately 200 Å. When the thickness of the adhesive layer 23 is less than approximately 100 Å, insufficient adhesion may occur in the interface between the photoresist layer pattern 24 and the insulation layer 22. When the thickness of the adhesive layer 23 exceeds approximately 200 Å, a subsequent process of etching the adhesive layer 23 becomes difficult and more time is needed for the process of etching the adhesive layer 23, which increases the possibility of damaging the constituent structure that is already formed.

Subsequently, the photoresist layer pattern 24 opening the first region and the second region is formed over the adhesive layer 23. For example, when a predetermined constituent structure is to be formed in the first region, which is the cell region, the photoresist layer pattern 24 may be formed using a cell open mask. When a predetermined constituent structure is to be formed in the second region, which is the peripheral circuit region, the photoresist layer pattern 24 may be formed using a peripheral open mask.

Referring to FIG. 3B, the adhesive layer 23 is etched using the photoresist layer pattern 24 as an etch barrier. Hereafter, the etched adhesive layer 23 will be referred to as an adhesive layer pattern 23A.

The process of etching the adhesive layer 23 may be performed using a wet etch method, and a mixed solution (HNO₃/HF) prepared by mixing nitric acid (HNO₃) and hydrofluoric acid (HF) in a predetermined ratio may be used as an etchant. To be specific, the etchant may a mixed solution prepared by mixing nitric acid (HNO₃) and hydrofluoric acid (HF) in a mixing ratio of approximately 300:1 (HNO₃:HF). Herein, the mixed solution (HNO₃:HF=300:1) of nitric acid (HNO₃) and hydrofluoric acid (HF) has an selectivity of approximately 1:0.2:106 (oxide layer:nitride layer:silicon layer) with respect to an oxide layer, a nitride layer, and a silicon layer. The etch rate for the silicon layer is approximately 40 Å per second in a temperature range of approximately 22° C. to approximately 25° C. Therefore, the process of etching the adhesive layer 23 may be performed for approximately 5 seconds to approximately 10 seconds.

Also, the process of etching the adhesive layer 23 may be performed using a single wet etch tool in order to prevent cross-contamination with the photoresist layer pattern 24 between the processes.

Referring to FIG. 3C, the insulation layer 22 is etched using the photoresist layer pattern 24 and the adhesive layer pattern 23A as etch barriers. Hereafter, the etched insulation layer 22 will be referred to as an insulation layer pattern 22A.

The process of etching the insulation layer 22 may be performed using a wet etch method. Herein, buffered oxide etchant (BOE) may be used as an etchant. The insulation layer 22 is etched using a wet etch method to protect a constituent structure formed in the first region that is opened through the etch process from being damaged during the etch process.

A portion of a sidewall of the insulation layer pattern 22A, revealed as the insulation layer 22 is etched, may be etched in a direction toward the second region, but the adhesive layer pattern 23A interposed between the insulation layer pattern 22A and the photoresist layer pattern 24 prevents the etchant from permeating toward the second region along the interface between the insulation layer pattern 22A and the photoresist layer pattern 24 and over-etching the insulation layer pattern 22A. Also, the adhesive layer pattern 23A protects the constituent structure formed in the second region from being damaged by the etchant as the insulation layer pattern 22A is over-etched.

Referring to FIG. 3D, the photoresist layer pattern 24 and the adhesive layer pattern 23A are sequentially removed and a predetermined constituent structure is formed in the first region opened by the insulation layer pattern 22A.

Herein, the photoresist layer pattern 24 may be removed through an ashing process or a cleaning process using a sulfuric acid hydrogen peroxide mixture (SPM) solution, which is a mixed solution of sulfuric acid (H₂SO₄) and hydrogen peroxide (H₂O₂). The adhesive layer pattern 23A may be removed through a wet etch process using the mixed solution of nitric acid (HNO₃) and hydrofluoric acid (HF), which has been described before with reference to FIG. 3B.

The technology of the present invention may improve the adhesion between the photoresist layer pattern and the insulation layer by forming an adhesive layer between the photoresist layer pattern and the insulation layer. With the improved adhesion between the photoresist layer pattern and the insulation layer, it is possible to prevent the etchant from permeating into the interface between the photoresist layer pattern and the insulation layer and over-etching the insulation layer during a process of wet-etching the insulation layer by using the photoresist layer pattern as an etch barrier.

While the present invention has been described with respect to exemplary embodiments, it will be apparent to those skilled in the art that various changes and modifications may be made without departing from the spirit and scope of the invention as defined by the following claims.

What is claimed is:

1. A method for fabricating a semiconductor device, comprising:
providing a substrate;
forming an insulation layer, an adhesive layer, and a photoresist pattern on the substrate;
etching the adhesive layer using the photoresist pattern as an etch barrier; and
wet etching the insulation layer using the etched adhesive layer and the photoresist pattern as etch barriers.

2. The method of claim 1, wherein the adhesive layer comprises a silicon layer.

3. The method of claim 1, wherein the adhesive layer comprises a monosilicon layer.

4. The method of claim 2, wherein the etching of the adhesive layer is performed using a mixed solution of nitric acid (HNO₃) and hydrofluoric acid (HF).

5. The method of claim 4, wherein the etching of the adhesive layer is performed using a mixed solution of nitric acid (HNO₃) and hydrofluoric acid (HF) in a mixing ratio of 300:1 (HNO₃:HF) in a temperature range of approximately 22° C. to approximately 25° C. for approximately 5 seconds to approximately 10 seconds.

6. The method of claim 3, wherein the etching of the adhesive layer is performed using a mixed solution of nitric acid (HNO₃) and hydrofluoric acid (HF).

7. The method of claim 6, wherein the etching of the adhesive layer is performed using a mixed solution of nitric acid (HNO₃) and hydrofluoric acid (HF) in a mixing ratio of 300:1 (HNO₃:HF) in a temperature range of approximately 22° C. to approximately 25° C. for approximately 5 seconds to approximately 10 seconds.

8. The method of claim 1, wherein a thickness of the adhesive layer ranges from approximately 100 Å to approximately 200 Å.

9. A method for fabricating a semiconductor device, comprising:
providing a substrate including a cell region and a peripheral circuit region;
forming an insulation layer and a silicon layer on the substrate;
forming a photoresist pattern on the silicon layer using a cell open mask;
etching the silicon layer using the photoresist pattern as an etch barrier; and
wet etching the insulation layer using the silicon layer and the photoresist pattern as etch barriers.

10. The method of claim 9, further comprising:
forming a cell gate in the cell region before the sequential forming of the insulation layer and the silicon layer on the substrate.

11. The method of claim 9, wherein the silicon layer comprises a monosilicon layer.

12. The method of claim 9, wherein the etching of the silicon layer is performed using a mixed solution of nitric acid (HNO₃) and hydrofluoric acid (HF).

13. The method of claim 12, wherein the etching of the silicon layer is performed using a mixed solution of nitric acid (HNO₃) and hydrofluoric acid (HF) in a mixing ratio of 300:1 (HNO₃:HF) in a temperature range of approximately 22° C. to approximately 25° C. for approximately 5 seconds to approximately 10 seconds.

14. The method of claim 9, wherein a thickness of the silicon layer ranges from approximately 100 Å to approximately 200 Å.
